(19) United States
(12) Patent Application Publication
(10) Pub. No.: US 2026/0066179 A1
(43) Pub. Date: Mar. 5, 2026

(54) PASSIVE ELECTRONIC DEVICE

(71) Applicant: STMicroelectronics International N.V., Geneva (CH)

(72) Inventor: Mohamed BOUTALEB, Tours (FR)

(73) Assignee: STMicroelectronics International N.V., Geneva (CH)

(21) Appl. No.: 19/300,520

(22) Filed: Aug. 14, 2025

(30) Foreign Application Priority Data
Aug. 27, 2024 (FR) FR2409148

(51) Int. Cl. H01F 27/28

(52) U.S. Cl. CPC H01F 27/2804; H01F 2027/2809

(57) ABSTRACT

The present disclosure relates to an integrated passive electronic device including a stack, in the order, starting from a top face of a support, of an insulating layer, a metal layer, and a passivating layer made of an electrically insulating material, the passivating layer coating the top face and side flanks of the metal layer, wherein a stress buffer layer made of another electrically insulating material different from the material of the passivating layer is formed on top edges of the metal layer between the metal layer and the passivating layer, the stress buffer layer being in contact with the metal layer.

### CROSS-REFERENCE TO RELATED APPLICATION(S)

This application claims the priority benefit of French patent application number 2409148, filed on Aug. 27, 2024, entitled “Dispositif électronique passif” which is hereby incorporated by reference to the maximum extent allowable by law.

### BACKGROUND

### Technical Field

The present description relates generally to passive electronic devices and more particularly to integrated passive electronic devices.

### Description of the Related Art

Integrated passive electronic devices correspond to passive electronic components, of the resistor, inductor, or capacitor type integrated alone or in groups in the same packaging, or on the same substrate or support.

It would be desirable to improve at least in part some aspects of such devices.

### BRIEF SUMMARY

To this end, one embodiment provides an integrated passive electronic device including a stack, in the order starting from a top face of a support, the support, an insulating layer, a metal layer, and a passivating layer made of an electrically insulating material, the passivating layer coating the top face and side flanks of the metal layer,
wherein a stress buffer layer made of another electrically insulating material different from the material of the passivating layer is formed on top edges of the metal layer between the metal layer and the passivating layer, the stress buffer layer being in contact with the metal layer.

According to an embodiment, the metal layer is made of copper.

According to an embodiment, the passivating layer is made of a polymer material.

According to an embodiment, the passivating layer is made of polybenzoxazole, benzocyclobutene, or a polyimide.

According to an embodiment, the stress buffer layer is made of silicon nitride, alumina, aluminum oxide or aluminum nitride.

According to an embodiment, the stress buffer layer extends starting from the edges of the metal layer on the top face and side flanks of the metal layer over a width greater than 1.5 μm.

According to an embodiment, the stress buffer layer coats a bottom part of the side flanks of the metal layer.

According to an embodiment, the device includes, between the insulating layer and the metal layer, other insulating and metal layers.

According to an embodiment, the stress buffer layer is made of a material having a tensile strength greater than that of the material of the passivating layer.

According to an embodiment, the side flanks of the metal layer include a portion not coated with the stress buffer layer.

Another embodiment provides a method for fabricating an integrated passive electronic device including the consecutive following steps:
depositing a stress buffer layer on a stack including, in the order starting from a top face of a support, the support, an insulating layer, and a metal layer;
depositing a passivating layer made of an electrically insulating material, the passivating layer coating the stress buffer layer and the top face and side flanks of the metal layer,
the stress buffer layer being in contact with the metal layer, and being made of another electrically insulating material different from the material of the passivating layer.

According to an embodiment, the method comprises a step of isotropic etching of the stress buffer layer so as to remove a part of the stress buffer layer formed on the side flanks of the metal layer.

According to an embodiment, depositing the stress buffer layer is performed by a method of conformally depositing.

According to an embodiment, a part of the stress buffer layer located in line with a center part of the metal layer is removed.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1A is a partial schematic sectional view, illustrating an example passive electronic device;

FIG. 1B is a graph illustrating the distribution of mechanical stress within the passive electronic device shown in FIG. 1A;

FIG. 2 is a partial schematic sectional view, illustrating an example passive electronic device according to a first embodiment;

FIG. 3 is a partial schematic sectional view, illustrating an example passive electronic device according to a second embodiment; and

FIG. 4 is a partial schematic sectional view, illustrating an example passive electronic device according to a third embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10% or 10°, and preferably within 5% or 5°.

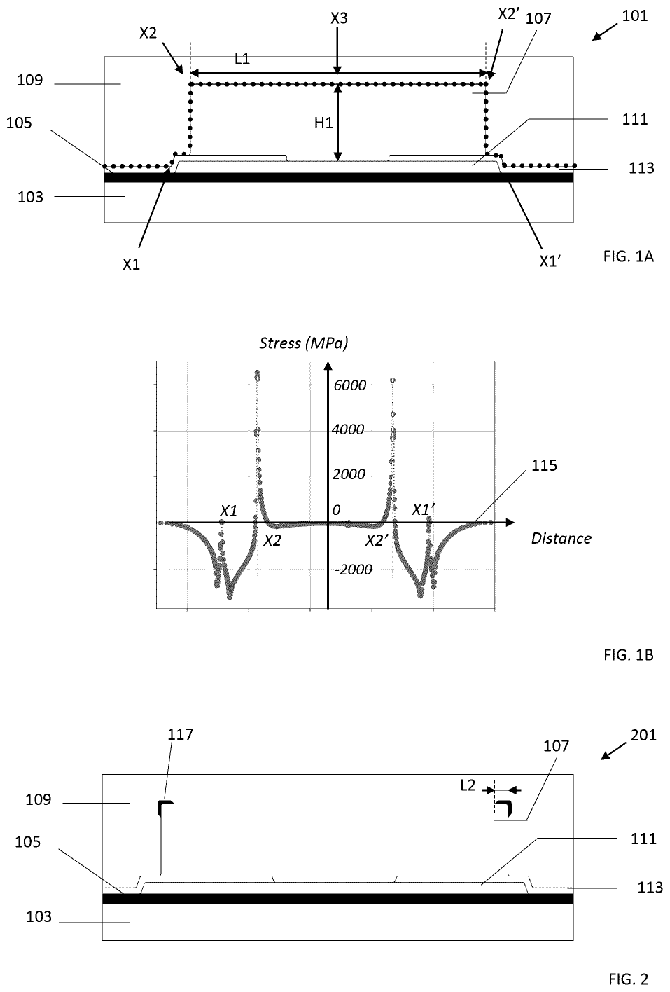

FIG. 1A is a partial schematic sectional view, illustrating an example passive electronic device 101.

The device 101 includes a support 103 on which is formed a stack including, in the order starting from a top face of the support 103, the support 103, an insulating layer 105, a metal layer 107, and a passivating layer 109.

As an example, the device 101 further includes, between the insulating layer 105 and the metal layer 107, another metal layer 111 coated with another insulating layer 113.

As an example, the support 103 is made of a semiconductor material, e.g., silicon, such as high resistivity silicon, or non-semiconductor material, such as glass. As an example, the support substrate 103 is made of a material having an electrical resistivity greater than 2.5 KΩ·cm.

The insulating layer 105 is for example in contact, via its bottom face, with the top face of the support 103. As an example, the insulating layer 105 coats the whole top face of the support 103. As an example, the insulating layer 105 is a layer made of a dielectric material, for example an oxide, e.g., an undoped silicate glass (USG). As an example, the insulating layer 105 has a thickness ranging from 0.5 μm to 5 μm, for example around 1.2 μm.

As an example, the metal layer 111 is formed on, and for example in contact via its bottom face with the top face of the insulating layer 105. The metal layer 111 extends for example on only a part of, the surface of the insulating layer 105. As an example, the metal layer 111 is made of aluminum. As an example, the metal layer 111 has a thickness ranging from 0.5 μm to 5 μm, for example around 1.5 μm.

As an example, the insulating layer 113 coats the metal layer 111 and a portion of the insulating layer 105 not coated with the metal layer 111, around the metal layer 111. As an example, the insulating layer 113 is in contact, via its bottom face, with the top face of the metal layer 111 and a portion of the top face of the insulating layer 105. As an example, the insulating layer 113 coats the whole metal layer 111 except for a central part of the metal layer 111 being not coated with the insulating layer 113. As an example, the insulating layer 113 further coats the side flanks of the metal layer 111. The insulating layer 113 is for example made of a dielectric material, for example an oxide, such as an undoped silicon silicate glass (USG). As an example, the insulating layer 113 has a thickness ranging from 0.1 μm to 2 μm, for example around 0.8 μm.

The metal layer 107 coats the insulating layer 105. As an example, the metal layer 107 coats only a part of the insulating layer 105. In the example shown in FIG. 1A, the metal layer 107 further coats the insulating layer 113 and the part of the metal layer 111 not coated with the insulating layer 113. As an example, the metal layer 107 is formed in line with the metal layer 111 and has, when viewed from above, a surface at a level lower than the surface of the metal layer 111. As an example, the bottom face of the metal layer 107 is in contact with a part of the top face of the insulating layer 113 and the part of the top face of the metal layer 111 not coated with the insulating layer 113. As an example, the metal layer 107 has a width L1 ranging from 10 μm to 275 μm, for example around 263 μm. For example, the metal layer 107 is made of copper. The metal layer 107 extends for example over a height H1 ranging from 3 μm to 15 μm, for example around 10 μm.

The passivating layer 109 coats for example the structure formed by the layers 105, 111, 113, and 107. More particularly, the passivating layer 109 coats the top face and the side flanks of the metal layer 107. The passivating layer 109 further coats the portion of the top face of the insulating layer 113 not coated with the metal layer 107. As an example, the passivating layer 109 has a flat top face. The passivating layer 109 is for example made of an electrically insulating material. The passivating layer 109 is for example made of a polymer material, for example of polybenzoxazole (PBO), of benzocyclobutene (BCB), and/or of a polyimide (PI). As an example, the passivating layer 109 extends above the metal layer 107 over a thickness ranging from 2 μm and 6 μm, for example ranging from 3 μm and 4 μm.

As an example, device 101 corresponds to an integrated passive device (IPD) including a resistor, an inductor, and a capacitor.

As an example, the metal layers 107 and 111 have, when viewed from above, a spiral shape extending on the surface of the support 103. The assembly formed by the layers 105, 111, 113, and 107 thus corresponds to a coil or inductor of the IPD device 101. Alternatively, the metal layers 107 and 111 have, when viewed from above, a round, square, rectangular shape, or any other. As an alternative, the device 101 corresponds to a passive component other than an inductor, for example a resistor or a capacitor.

The support 103 supports for example one or more other components, not shown, such as capacitors or resistors, formed in the vicinity of the inductor, and electrically connected to the inductor.

In such a device, the inventors noticed that during thermal cycles, within tests of temperature reliability of devices 101, the passivating layer 109 has cracks extending through the thickness of the passivating layer 109, starting from the top edges of the metal layer 107. Such cracks could pass through the thickness of the passivating layer 109 to reach for example the top face of the passivating layer 109. By top edges of the metal layer 107, we mean the junctions between the top face of the metal layer 107 and each of the side flanks of the metal layer 107.

Such cracks could cause a delamination of the metal layer 107 or of the passivating layer 109, and affect the reliability and the lifetime of the components.

FIG. 1B is a graph illustrating the distribution of mechanical stress undergone within the passive electronic device shown in FIG. 1A during thermal cycles.

The graph shown in FIG. 1B illustrates, with a curve 115, the mechanical stress (Stress) received and cumulated along the bottom face of the passivating layer 109, shown with a dotted line in FIG. 1A. More particularly, in the graph of FIG. 1B, the curve 115 represents the evolution of the stress (Stress), in y-axis, in megapascals (MPa), as a function of the location (Distance), in micrometers, along the bottom face of the passivating layer 109, the origin of which is located, in X3, opposite the center of the metal layer 107.

The evolution of the stress along the bottom face of the passivating layer 109 shows that the stress is negative and minimum, at X1 and X1′, either side of the metal layer 107, in line with the layer 113, when the latter is in contact with the layer 105. This negative value of stress means that the received stress is a compressive stress.

Along the bottom face of the passivating layer 109, in a direction towards the center of the metal layer 107, the stress then increases to reach a positive and maximum stress, at X2 and X2′ on the edges of the metal layer 107. This positive value of the stress means that the received stress is a tensile stress.

Along the center part of the metal layer 107, the stress decreases again starting from the edges of the metal layer 107, to reach a constant value, here zero, at X3 at the center of the metal layer 107. This zero value of the stress means that at these locations of the bottom face of the passivating layer 109, the layer undergone neither tensile stress, nor compressive stress.

The variation of the stress is explained by the fact that the electronic device 101 is formed by a series of several layers of different natures and materials. Particularly, these layers have different thermo-mechanical behaviors, and more particularly, have different coefficients of thermal expansion.

During thermal cycles, the thermal expansions of the different layers cumulate with each other by generating a stress on the bottom face of the passivating layer 109. When the stress locally received is greater than the tensile strength (expressed in MPa or N/mm²), the passivating layer 109 cracks by creating, starting from the tensile strength value, the cracks mentioned in reference to FIG. 1A.

FIG. 2 is a partial schematic sectional view illustrating an example passive electronic device 201 according to a first embodiment. The device of FIG. 2 comprises the same elements of the device shown in FIG. 1, significantly arranged the same way, and differs from the device shown in FIG. 1 in that it further includes a stress buffer layer (SBL) 117 between the metal layer 107 and the passivating layer 109.

In the embodiment shown in FIG. 2, the stress buffer layer 117 is formed on the top edges of the metal layer 107.

The stress buffer layer 117 is made of a material having for example a tensile strength greater than that of the material of the passivating layer 109. The stress buffer layer 117 is a layer made of a material different from the passivating layer 109. As an example, the stress buffer layer 117 is made of an insulating material, for example a dielectric material. The stress buffer layer 117 is for example made of silicon nitride, alumina, aluminum oxide or aluminum nitride.

As an example, the stress buffer layer 117 is formed on the edges of the metal layer 107, and extends starting from the edges, on the side and top faces of the metal layer 107 over a width L2 greater than 1 μm, for example greater than 1.5 μm. The stress buffer layer 117 is in contact, via its bottom face, with the top face of the metal layer 107. As an example, the stress buffer layer 117 is in contact, via its top face, with the bottom face of the passivating layer 109.

As an example, the stress buffer layer 117 is formed at the end of forming the metal layer 107 on the stack formed by the layers 105, 111, and 113 on the top face of the support 103. As an example, the stress buffer layer 117 is formed before the passivating layer 109 is formed. The stress buffer layer 117 is for example formed whole wafer, i.e., on the whole top face of the above-mentioned assembly. As an example, the stress buffer layer 117 is deposited by an evaporative deposition method. Alternatively, the stress buffer layer 117 is deposited by a spray deposition method. Yet alternatively, the stress buffer layer 117 is deposited by an atomic layer deposition (ALD) method. The stress buffer layer 117 is for example conformally formed with a thickness ranging from 0.2 μm to 5 μm, for example of the order of 1 μm.

As an example, following its deposition, the stress buffer layer 117 is locally removed so as to be kept only on and in the vicinity of the edges of the metal layer 107. As an example, locally removing the stress buffer layer 117 is performed by an isotropic-type etching so as to be able to remove portions of the stress buffer layer 117 on the side and top flanks of the metal layer 107.

As an example, locally removing the stress buffer layer 117 is performed by wet etching. Alternatively, locally removing the stress buffer layer 117 is performed by physical etching, such as by non-polarized plasma.

As an example, at the end of forming the stress buffer layer 117, the metal layer 107 has a bottom part of its side flanks exposed and non-coated with the stress buffer layer 117. As an example, at the end of forming the stress buffer layer 117, the metal layer 107 has a center part of its top face free and not coated with the stress buffer layer 117.

As an example, although it is not shown in FIG. 2, at the end of forming the passivating layer 109, the latter could be etched so as to form a through hole therein, opening on the top face of the metal layer 107, allowing, using a conductive layer, a contact with the metal layer 107 to be formed.

One advantage of the present embodiment is it allows the thermal expansion at the interface of layers 107 and 109 to be absorbed, and the stress received by the bottom face of the passivating layer 109 in line with the stress buffer layer 117 to be restricted.

Another advantage of the present embodiment is that the stress received by the bottom face of the passivating layer 109 is less than the tensile strength, thus reducing the chances of forming cracks within the passivating layer 109.

Yet a further advantage of the present embodiment is that the stress buffer layer 117 allows the stress cumulated at the edges of the metal layer 107, over the whole top face of the metal layer 107, to be redistributed.

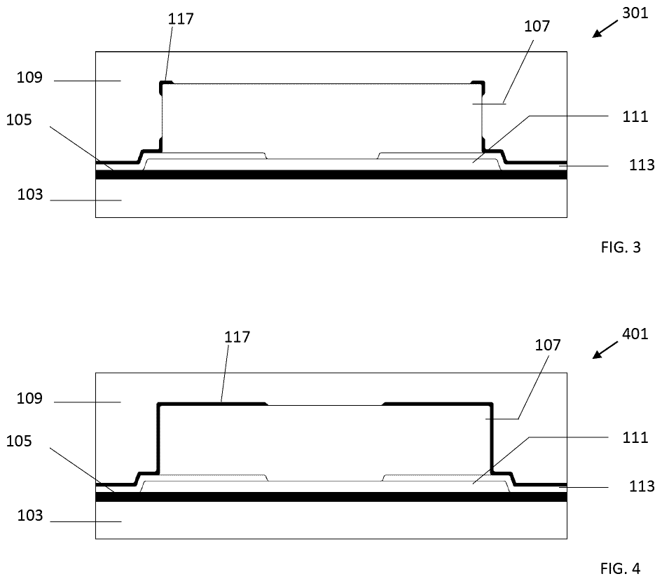

FIG. 3 is a partial schematic sectional view, illustrating an example passive electronic device 301 according to a second embodiment.

More particularly, FIG. 3 illustrates a device 301 similar to the device 201 shown in FIG. 2, with the difference that in the device 301 shown in FIG. 3, the stress buffer layer 117 extends over a bottom part of the side flanks of the metal layer 107, and over the top face of the oxide layer 113 around the metal layer.

FIG. 4 is a partial schematic sectional view, illustrating an example passive electronic device 401 according to a third embodiment.

More particularly, FIG. 4 illustrates a device 401 similar to the device 201 shown in FIG. 2, with the difference that in the device shown in FIG. 4, the stress buffer layer 117 extends over the whole side flanks of the metal layer 107. In this embodiment, the stress buffer layer 117 extends in addition over the top face of the oxide layer 113, around the metal layer 107. Further, in this embodiment, the stress buffer layer 117 extends on the top face of the metal layer 107 over a greater surface area than that was described in the embodiment shown in reference to FIG. 2. In this embodiment, the stress buffer layer 117 extends on the whole surface of the top face of the metal layer except for a center portion of a width ranging from 10 μm and 75 μm, for example in the order of 30 μm, allowing the contact with the metal layer 107.

In this embodiment, contrary to that has been described in reference to FIG. 2, etching the stress buffer layer could be anisotropically etching. Indeed, the portions of the stress buffer layer 117 present on the side flanks of the metal layer 107 are kept in this embodiment.

One advantage of the third embodiment is it allows the stress buffer layer 117 to be kept in place on the flanks of the metal layer 107, and thus the step(s) of etching the stress buffer layer 117 following depositing it to be simplified.

Numerous applications are likely to benefit from the advantages provided by the electronic device 201, this device 201 thus could be integrated in various types of components.

As an example, the device 201 could be integrated in a component dedicated to automotive industry. Electrifying automotive vehicles causes a high increase in the number of electronic components present in the vehicles. As an example, the device 201 could be integrated in a component dedicated to industry. Particularly, the component is for example used in developing green energies or electrifying infrastructure, for example in charging stations or collecting solar energy. The component could also be used in the field of Internet of Things, or in the field of smart home. The component is for example intended to be implemented in circuits for supplying equipment with electric power. The component could also be used in implementing computer systems in cloud, 5G RF communications network, datacenters, and servers.

As an example, the device 201 could be integrated in a component intended to be used in personal electronics, for example implementing RF communications, in 5G communications systems, or more generally in any connected component. The component is for example a mobile phone, or smartphone, or is a part of an Internet of Things network. For example, the component is connected via 5G, or via WiFi, or via broadband communications. For example, the component comprises high-speed interfaces, for example with advanced filtering and electrostatic discharges protection.

As an example, the device 201 could be integrated in a component intended to be used in communications equipment, or in computers and peripherals. For example, the component is used in 5G infrastructures and dedicated datacenters. The component could also be used in satellites comprising for example integrated passive components for RF applications.

Various embodiments and variants have been described. Those skilled in the art will understand that certain features of these embodiments can be combined and other variants will readily occur to those skilled in the art. In particular, although the stack formed by the layers 103, 105, 107, and 109 herein corresponds to the stack of a capacitor, one could provide a stress buffer layer 117 such as described in the embodiments of FIGS. 2 to 4 could be formed in other types of passive components such as inductor (or coil) or resistors. Further, such a stress buffer layer could be formed more generally at the interface between a metal layer, for example made of copper, and a passivating layer, for example made of a polymer material, e.g., PBO, BCB, or polyimide, in order to reduce the stress formed on the edges of the copper layer.

Finally, the practical implementation of the embodiments and variants described herein is within the capabilities of those skilled in the art based on the functional description provided hereinabove.

An integrated passive electronic device (201; 301; 401) is summarized as including a stack, in the order starting from a top face of a support, the support, an insulating layer (113), a metal layer (107), and a passivating layer (109) made of an electrically insulating material, the passivating layer (109) coating the top face and side flanks of the metal layer (107), wherein a stress buffer layer (117) made of another electrically insulating material different from the material of the passivating layer (109) is formed on top edges of the metal layer (107) between the metal layer (107) and the passivating layer (109), the stress buffer layer (117) being in contact with the metal layer (107).

The metal layer (107) is made of copper.

The passivating layer (109) is made of a polymer material.

The passivating layer (109) is made of polybenzoxazole, benzocyclobutene, or a polyimide.

The stress buffer layer (117) is made of silicon nitride, alumina, aluminum oxide or aluminum nitride.

The stress buffer layer (117) extends from the edges of the metal layer (107) on the top face and side flanks of the metal layer (107) over a width (L2) greater than 1.5 μm.

The stress buffer layer (117) coats a bottom part of the side flanks of the metal layer (107).

The device includes, between the insulating layer (105) and the metal layer (109), other insulating (113) and metal (111) layers.

The stress buffer layer (117) is made of a material having a tensile strength greater than that of the material of the passivating layer (109).

The side flanks of the metal layer (107) include a portion not coated with the stress buffer layer (117).

A method for fabricating an integrated passive electronic device (201; 301; 401) is summarized as including the consecutive following steps: depositing a stress buffer layer (117) on a stack including, in the order starting from a top face of a support (103), the support (103), an insulating layer (113), and a metal layer (107); depositing a passivating layer (109) made of an electrically insulating material, the passivating layer (109) coating the stress buffer layer (117) and the top face and side flanks of the metal layer (107), the stress buffer layer (117) being in contact with the metal layer (107), and being made of another electrically insulating material different from the material of the passivating layer (109).

The method further includes a step of isotropic etching of the stress buffer layer (117) so as to remove a part of the stress buffer layer (117) formed on the side flanks of the metal layer (107).

Depositing the stress buffer layer (117) is performed by a method of conformally depositing.

A part of the stress buffer layer (117) located in line with a center part of the metal layer (107) is removed.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated passive electronic device comprising:
a stack, in the order starting from a top face of a support, the support, an insulating layer, a metal layer, and a passivating layer made of an electrically insulating material, the passivating layer coating the top face and side flanks of the metal layer, and
a stress buffer layer made of another electrically insulating material having a tensile strength greater than a tensile strength of the material of the passivating layer, the stress buffer layer formed on top edges of the metal layer between the metal layer and the passivating layer, the stress buffer layer being in contact with the metal layer.

2. The device according to claim 1, wherein the metal layer is made of copper.

3. The device according to claim 1, wherein the passivating layer is made of a polymer material.

4. The device according to claim 1, wherein the passivating layer is made of polybenzoxazole, benzocyclobutene, or a polyimide.

5. The device according to claim 1, wherein the stress buffer layer is made of silicon nitride, alumina, aluminum oxide or aluminum nitride.

6. The device according to claim 1, wherein the stress buffer layer extends starting from the edges of the metal layer on the top face and side flanks of the metal layer over a width greater than 1.5 μm.

7. The device according to claim 1, wherein the stress buffer layer coats a bottom part of the side flanks of the metal layer.

8. The device according to claim 1, further comprising other insulating layer and other metal layer between the insulating layer and the metal layer.

9. The device according to claim 1, wherein the side flanks of the metal layer include a portion not coated with the stress buffer layer.

10. A method for fabricating an integrated passive electronic device, comprising:
depositing a stress buffer layer on a stack, the stack including a support, an insulating layer on a top face of the support, and a metal layer on the insulating layer, and the stress buffer layer being in contact with the metal layer; and
depositing a passivating layer of an electrically insulating material, the passivating layer coating the stress buffer layer and the top face and side flanks of the metal layer, the stress buffer layer of another electrically insulating material having a tensile strength greater than a tensile strength of the material of the passivating layer.

11. The method according to claim 10, further comprising isotropic etching the stress buffer layer to remove a part of the stress buffer layer on the side flanks of the metal layer.

12. The method according to claim 10, wherein depositing the stress buffer layer is conformally depositing.

13. The method according to claim 10, further comprising removing a part of the stress buffer layer located in line with a center part of the metal layer.

14. An electronic device, comprising:
an insulating layer;
a metal layer on the insulating layer, the metal layer having a top surface and side flanks, the side flanks connected to the top surface at edges of the metal layer;
a stress buffer layer covering edges of the metal layer; and
a passivating layer covering the insulating layer, the metal layer, and the stress buffer layer, and a tensile strength of the stress buffer layer greater than a tensile strength of the passivating layer.

15. The electronic device according to claim 14, wherein side flanks of the metal layer are covered by the stress buffer layer.

16. The electronic device according to claim 14, wherein a bottom part of each side flanks of the metal layer is covered by the stress buffer layer.

17. The electronic device according to claim 14, wherein the stress buffer layer is made of silicon nitride, alumina, aluminum oxide or aluminum nitride.

18. The electronic device according to claim 14, further comprising:
another metal layer between the metal layer and the insulating layer; and
another insulating layer between the metal layer and the another metal layer, the another insulating layer covering side flanks of the another metal layer and a part of the insulating layer not covered by the metal layer, and the another insulating layer between the stress buffer layer and the insulating layer.

19. The electronic device according to claim 18, wherein the another insulating layer has a first opening, the metal layer protrudes into the opening and electrically coupled to the another metal layer, the stress buffer layer has a second opening exposing a part of the top surface of the metal layer, and the first opening is in line with the second opening.

20. The electronic device according to claim 14, wherein a width of the stress buffer layer extending from the edges on the top surface of the metal layer is greater than 1 μm.
